(19) United States
(12) Patent Application Publication
(10) Pub. No.: US 2025/0140760 A1
(43) Pub. Date: May 1, 2025

(54) ARTICLES AND METHODS RELATED TO CIRCULAR POLARIZED LEDS

(71) Applicants: Shaohua Huang, Taichung City (TW); Troy Hsu, Quanzhou (CN); Nathaniel Huber, Los Angeles, CA (US); Thomas R. Jory, Santa Cruz, CA (US); XinLong Li, Quanzhou (CN)

(72) Inventors: Shaohua Huang, Taichung City (TW); Troy Hsu, Quanzhou (CN); Nathaniel Huber, Los Angeles, CA (US); Thomas R. Jory, Santa Cruz, CA (US); XinLong Li, Quanzhou (CN)

(21) Appl. No.: 18/813,472

(22) Filed: Aug. 23, 2024

Related U.S. Application Data
(63) Continuation-in-part of application No. 18/497,218, filed on Oct. 30, 2023.

(51) Int. Cl. H01L 25/075; H01L 25/13

(52) U.S. Cl. CPC H01L 25/0753; H01L 25/13

(57) ABSTRACT

The present disclosure is generally related to LED packages with integrated light polarizers, for example, for generating 3D images. Some aspects are generally directed to having a light polarizer directly integrated within the LED package, for instance, without air between the light polarizer and the LEDs of each pixel and/or such that a relatively opaque side wall may surround the light polarizer. In some cases, direct integration of the light polarizer may minimize stray light between pixels to improve contrast ratio and/or image quality of the LED package. In some embodiments, the LED packages with integrated light polarizers are constructed such that every other pixel of the LED package emits left circularly polarized light, and the remaining pixels emit right circularly polarized light. Other aspects are related to methods of making and/or using the LED packages, or the like.

### RELATED APPLICATIONS

This application is a continuation-in-part of U.S. application Ser. No. 18/497,218, filed Oct. 30, 2023, and entitled “ARTICLES AND METHODS RELATED TO CIRCULAR POLARIZED LEDS,” which is incorporated herein by reference in its entirety for all purposes.

### TECHNICAL FIELD

The present disclosure is generally related to LED packages with integrated light polarizers, for example, for generating 3D images.

### BACKGROUND

To polarize light from LED packages, remote films are typically placed in the optical path of the light emitted from each LED package. Placing remote films on top of each LED package (e.g., pixel) within an LED display requires downstream manufacturing after the initial LED display fabrication, which can lead to increased costs for LED manufacturers. Moreover, stray light between the pixels and the remote films can lower contrast ratios and thus image quality generated by LED displays. Accordingly, improved LED packages, and corresponding methods for manufacturing, are needed.

### SUMMARY

The present disclosure is generally related to LED packages with integrated light polarizers, for example, for generating 3D images.

Some aspects are related to methods.

In some embodiments, the method is a method of manufacturing a circularly polarized LED display. In some embodiments, the method comprises providing a plurality of LED packages, each of the plurality of the LED packages comprising: a red LED die in electrical communication with a substrate; a green LED die in electrical communication with the substrate; a blue LED die in electrical communication with the substrate; and an intervening layer formed over each of the LED dies; forming an adhesive layer over each of the plurality of LED packages; and placing a light polarizer over each of the plurality of LED packages, each of the light polarizers configured to polarize light emitted from the LED packages; and dispensing a side wall material between adjacent LED packages.

Some aspects are related to LED displays.

In some embodiments, the LED display comprises a plurality of LED packages, each of the plurality comprising: a substrate; a red LED die in electrical communication with the substrate; a green LED die in electrical communication with the substrate; a blue LED die in electrical communication with the substrate; an intervening layer formed over each of the LED dies; an adhesive layer formed over the intervening layer; a light polarizer formed over the adhesive layer, the light polarizer configured to polarize light emitted from the LED dies; and a side wall extending vertically from the substrate, the side wall including an upper overhanging portion that extends over a section of the light polarizer; and a protective layer formed over the plurality of LED packages.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 is an illustrative diagram of a plurality of LED packages, according to some embodiments;

FIG. 2A-G are illustrative diagrams at different stages during a method for making an LED package, according to some embodiments;

FIG. 2H is a top-down view of a schematic diagram of a plurality of LED packages, according to some embodiments;

FIG. 3A is an illustrative diagram of a light polarizer, according to some embodiments;

FIGS. 3B-C are illustrative diagrams showing the light distribution of an LED package with and without an overhanging structure, according to some embodiments;

FIGS. 3D-E are optical micrographs showing a side view of LED packages with and without an overhanging structure, according to some embodiments;

FIG. 4 is an illustrative diagram showing the orientation of LEDs on a substrate, according to some embodiments;

FIG. 5 is an illustrative diagram of how a plurality of pixels is arranged to emit left and right circular polarized light, according to some embodiments;

FIGS. 6A-6G are illustrative diagrams at different stages during a method for making an LED display, according to some embodiments; and

FIGS. 7A and 7B are images of LED displays, according to some embodiments.

### DETAILED DESCRIPTION

The present disclosure is generally related to LED packages with integrated light polarizers, for example, for generating 3D images. Some aspects are generally directed to having a light polarizer directly integrated within the LED package, for instance, without air between the light polarizer and the LEDs of each pixel and/or such that a relatively opaque side wall may surround the light polarizer. In some cases, direct integration of the light polarizer may minimize stray light between pixels to improve contrast ratio and/or image quality of the LED packages and/or LED display. In some embodiments, the LED packages with integrated light polarizers are constructed such that every other pixel of the LED package emits left circularly polarized light and the remaining pixels emit right circularly polarized light. Other aspects are related to methods of making and/or using the LED packages, or the like.

Conventionally, to polarize light from LED displays, remote films (e.g., a film not integrated within the LED package) are placed in the optical path of the LED light emitted from each pixel (e.g., LED package) of the LED display. Placing remote films on top of each pixel requires downstream manufacturing after the initial LED display fabrication, which can increase manufacturing costs. Moreover, due to the space between the pixel and the remote film, stray light may be emitted between the pixels. Stray light may lower contrast ratios between the pixels and thus detract from the image quality of the LED display. It should be understood that pixel and LED package are used interchangeably.

Accordingly, some aspects of the present disclosure are generally related to LED packages with integrated light polarizers. It may be advantageous to directly integrate the light polarizer into the LED package when compared to conventional LED packages with light polarizers, for example, wherein the light polarizer is a remote film on top of the LED package. Integrating the light polarizer may minimize and/or eliminate stray light between pixels while also extending the lifetime of the LED package, in some embodiments. For example, in some cases, a relatively opaque side wall (e.g., having a transmittance of less than or equal to 0.2, less than or equal to 0.1, less than or equal to 0.05, or other values as disclosed elsewhere herein) may surround each pixel comprising a light polarizer. Thus, the side wall, according to some embodiments, may minimize and/or eliminate stray light and/or non-polarized light from being emitted from the pixel. In some embodiments, a robust optical resin cap may be placed above the light polarizer to protect the light polarizer from damage, for example, by environmental factors if the LED package is used outdoors.

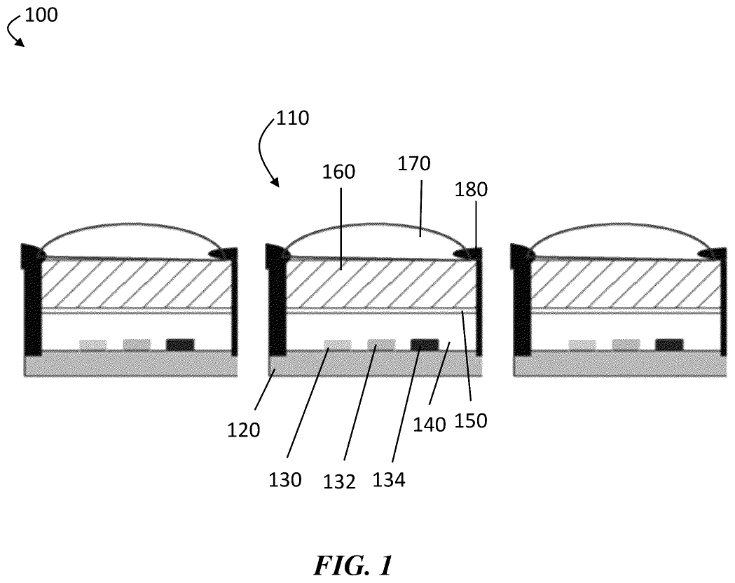

As a non-limiting example, consider FIG. 1 which shows an exemplary embodiment of an LED package comprising a plurality of pixels 100. Each pixel 110 in the plurality of pixels 100 comprises at least one red LED die 130, at least one green LED die 132, at least one blue LED die 134, an intervening layer 140, an adhesive layer 150, a light polarizer 160, side walls 180, and an optical resin cap (e.g., dome 170). The light polarizer 160 is integrated within each pixel 110 and is surrounded by side walls 180. In this configuration, the stray light and/or non-polarizing light emitted from each pixel should be minimized and/or eliminated. Additionally, the optical resin cap 170 in physical contact with the top surface of the light polarizer 160 may provide physical protection to the light polarizer and/or the other components of each pixel 110. As described elsewhere herein, it may be useful to construct each pixel to comprise some or all of the components illustrated in FIG. 1.

The discussion of the foregoing examples is non-limiting and is only meant to be an illustrative set of embodiments. Other configurations and embodiments of LED packages are possible. Additionally, systems and/or methods related to the LED packages are disclosed elsewhere herein.

Some aspects of the present invention are related to LED packages modified to emit polarized light. In some cases, the LED package integrates light polarizers, such as linear polarizers and/or quarter wave plates. LED packages with integrated light polarizers eliminate the need for downstream manufacturing steps to add remote films and minimize the distance between the LEDs and the light polarizers. These advantages can lead to lower manufacturing costs and improved contrast ratios between light emitted from a single pixel and/or between multiple pixels. Furthermore, incorporating different light polarizers (e.g., linear polarizers and/or different quarter wave plates corresponding to left and right circular polarizers) in different pixels may facilitate the LED package to be used for generating complex images, for example, 3D images. Arranging the pixels such that they emit light with different polarizations (e.g., left circular polarized or right circular polarized) in a periodic array may improve complex image generation. In some such cases, the light polarizers may be integrated into each pixel of the LED package, wherein different pixels may have different light polarizers to emit differently polarized light.

Various other components may also be incorporated into the LED package. For example, in some cases, there may be an intervening layer between the light polarizer and the substrate with the LEDs. The intervening layer may provide a level surface on which the light polarizer may be applied. In some embodiments, side walls comprising a relatively opaque material between pixels may be used, wherein the side walls may comprise a relatively opaque material which minimizes stray light between the pixels of the LED package. According to some embodiments, a robust optical resin cap may also be placed on top of a light polarizer to protect the light polarizer, which, in some cases, may improve the lifespan of the LED package.

Each pixel of the plurality of pixels may further comprise another layer on top of the light polarizer. The layer may comprise or be a relatively robust optical resin cap, configured to protect the LED package from being damaged during use. In some embodiments, each pixel of the plurality of pixels is surrounded by a side wall. In some embodiments, the side wall comprises a relatively optically opaque material to minimize stray light between pixels. According to some embodiments, the sides walls of each pixel are separated from the side walls other pixels such that the pixels of the plurality of pixels are singulated.

Certain aspects of the present invention are related to methods of making integrated LED packages with integrated light polarizers. In some cases, a substrate comprising a plurality of pixels is provided. Each pixel of the plurality of pixels may comprises at least one red LED die in electrical communication with the substrate, at least one green LED die in electrical communication with the substrate, and at least one blue LED die in electrical communication with the substrate. In some cases, an intervening layer comprising silicone is formed on top of the plurality of pixels, wherein each pixel is then separated by cutting the intervening layer along the boundaries of each pixel. An adhesive is then added above the intervening layer, in some embodiments, to which a light polarizer may be attached. The light polarizer may comprise a linear polarizer and a quarter wave plate. According to some embodiments, the substrate, the intervening layer, and the light polarizer may be exposed to a vacuum and then removed from the vacuum. In some cases, a side wall material may be dispensed between each pixel of the plurality of pixels, the side wall material being cured in some embodiments by heating plurality of pixels comprising the side wall material. In some cases, an optical resin cap may be dispensed above the light polarizer, whereafter the side wall material between each pixel may be singulated to form separate pixels (e.g., the side wall material of each pixel is physically separated) comprising of the plurality of pixels.

In some cases, methods of making the integrated LED package involve placing a light polarizer on each pixel of the LED package. In some cases, the light polarizer placed on a first half of the plurality of pixels is configured to left circular polarize light emitted from the LEDs and the light polarizer on a second half of the plurality of pixels is configured to right circular polarize light emitted from the LEDs.

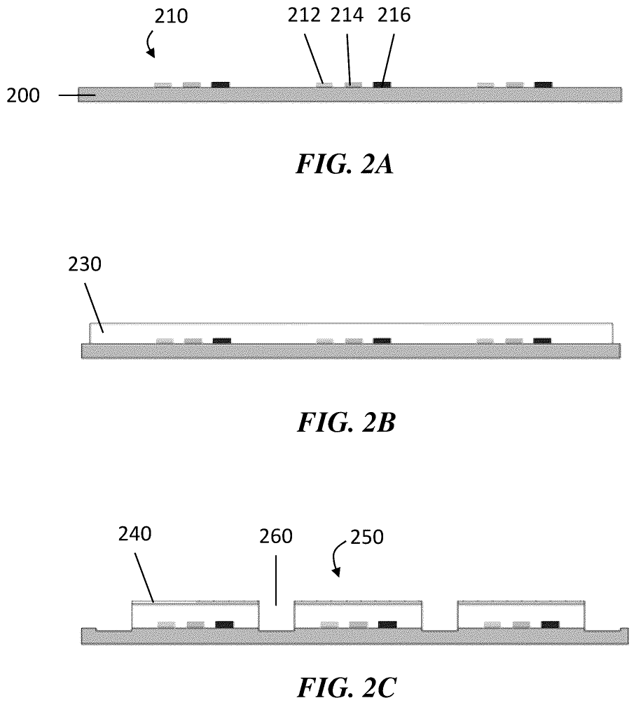

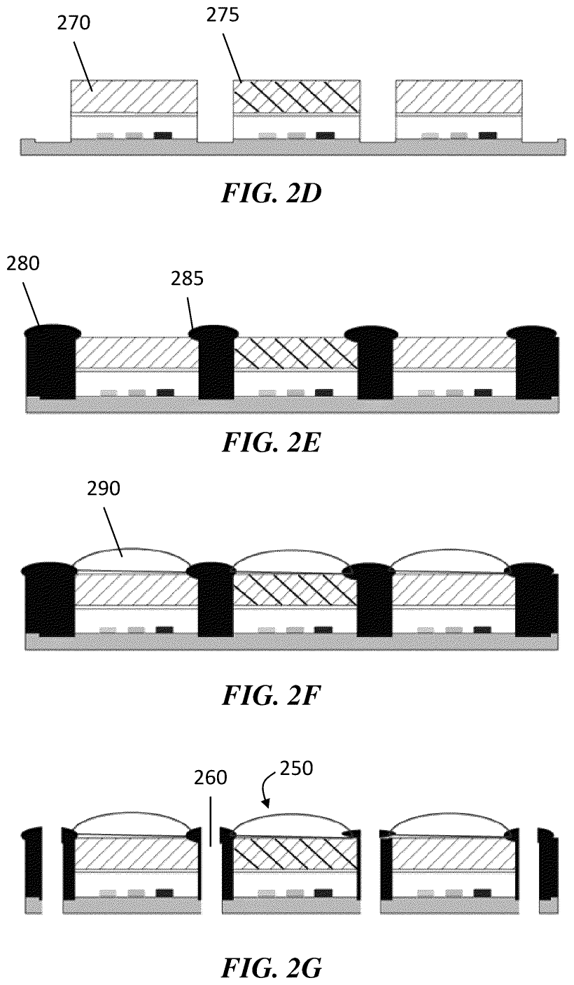

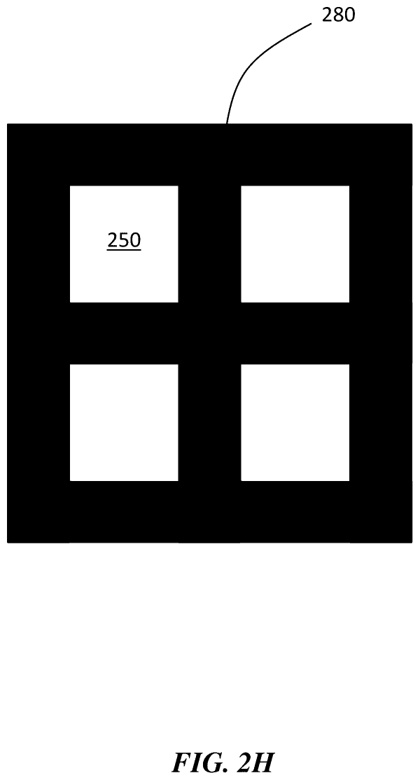

An exemplary embodiment of a method for making an LED package with integrated light polarizers is shown in FIGS. 2A-2G. FIG. 2A shows a substrate 200, such as a circuit board, comprising three pixels (e.g., LED packages) 210 comprising a red LED die 212, a blue LED die 214, and a green LED die 216. The LED dies are electrically connected to the substrate, for example, by soldering an electrical connection between each LED die and the substrate. Silicone is poured over the pixels of the LED package in FIG. 2B, forming an intervening layer 230 which levels the surface of each pixel. An adhesive layer 240 comprising epoxy is attached on top of the intervening layer, and the intervening layer and adhesive layer are then cut to form LED packages 250 wherein the intervening layers are separated by space 260 in FIG. 2C. FIG. 2D shows how individual light polarizers 270 and 275 are placed on top of the adhesive layer of each pixel. The light polarizer on each pixel is not necessarily the same, and in this example, the light polarizer alternates between a light polarizer configured to left circularly polarize light (270) and a light polarizer configured right circularly polarize light (275) from one pixel to the next. A side wall material 280 is then dispensed between the pixels of LED package, as shown in FIG. 2E. Note that while FIGS. 2A-G shows cross-sectional illustrations of the pixels of the LED package, the side wall material surrounds the perimeter of each pixel. Moreover, the side wall material may be over-dispensed to form an overhanging structure 285, which is located partially in the optical path of the light emitted from the LEDs. The overhanging structure may help mitigate stray light between adjacent pixels and/or minimize the amount of light emitted from the LEDs that does not pass through the light polarizer. FIG. 2F illustrates that an optical resin cap 290 is dispensed on top of the light polarizers of each pixel, after which each pixel is again singulated via conventional cutting methods to form separate LED packages 250 with spaces 260 therebetween in FIG. 2G.

The LED package may comprise a plurality of pixels on a substrate, wherein each pixel comprises at least one red LED die in electrical communication with the substrate, at least one green LED die in electrical communication with the substrate, and at least one blue LED die in electrical communication with the substrate. The substrate may be comprised of any of a variety of suitable materials. Exemplary substrates include circuit boards, two-layer circuit boards, flexible circuit boards, printed circuit boards, and ceramic materials with patterned circuit traces. Accordingly, in cases where the substrate comprises a circuit board, each LED of each pixel is in electrical communication with the circuit board. Electrical connections between the LEDs and the substrate may be achieved through any of a number of suitable methods, for example via low-temperature soldering, using electrical paste, and/or applying conductive glue. In some cases, low temperature soldering may be particularly advantageous to achieve robust electrical communication while avoiding damage to the LEDs in each pixel.

The shape and size of each pixel of the LED package may vary, according to the desired optical properties such as brightness, contrast ratio, and/or resolution. Each pixel may be square, circular, triangular, or any other regular or irregular shape. According to some embodiments, it may be particularly advantageous to the square pixels for simple fabrication and/or packing of the pixels on the substrate.

In some cases, the size of a pixel may vary, based on the size of the LEDs (e.g., which may correspond to the brightness of the LEDs) and/or desired image resolution of the final LED package.

The LED package may comprise any of a number of pixels suitable for different types and sizes of displays, as well as the desired resolution of the display.

According to some embodiments, each pixel of the plurality of pixels may have a number of layers and/or films on top of the LED dies and/or the substrate. In some cases, the layers and/or films may be formed over and/or formed directly on the LED dies and/or the substrate. Each of the layers and/or films is optically transparent and/or index matched with the other materials. These properties of the layers and/or films facilitate the light from the LEDs to be emitted from the LED package without undesirable effects such as differing amounts of reflection or refraction of the emitted light in and/or between the layers of the pixels that may lead to a corresponding decrease is brightness of the light emitted from the whole pixel (e.g., after passing through all the films and/or layers).

In some cases, each pixel has an intervening layer in contact with the LEDs and/or the substrate. In some embodiments, the intervening layer is formed over and/or formed directly on the LEDs and/or the substrate. The intervening layer may be present in order to facilitate the placement of additional films and/or layers on top of the pixel to alter the properties of the light emitted from the LEDs (e.g., polarization). That is, the intervening layer may provide a level surface on which other films and/or layers may be placed and/or to provide a uniform medium for which light emitted from the LEDs can pass. In some cases, the intervening layer may comprise a transparent molding compound. For example, it may be particularly advantageous if the intervening layer comprises silicone. In some such cases, the intervening layer may further comprise a diffusing powder present in the silicone. The silicone may be dispensed using a syringe configured to mix precursors, wherein the syringe dispenses liquid precursors which mix and form a layer that is substantially flat.

The diffusing powder may be present in the silicone in an amount of greater than or equal to 1 wt %. In some cases, the intervening layer may comprise the diffusing powder present in the silicone in an amount of less than or equal to 10 wt %. Other ranges are also possible.

According to some embodiments, the intervening layer may have a thickness of greater than or equal to 100 microns. In some cases, the intervening layer may have a thickness of less than or equal to 1 mm. Other ranges are also possible.

On top of the intervening layer, in order to facilitate the addition of another film and/or another layer, it may be useful to add an adhesive layer, according to some embodiments. In some cases, the adhesive layer is formed on and/or formed over the intervening layer. Exemplary adhesives include glues, silicones, and/or epoxies.

A light polarizer may also be placed above the intervening layer, according to some embodiments. In some cases, light polarizers may be formed on and/or formed over the intervening layer. Light polarizers may be used, for example, to polarize the light emitted from the LEDs. In some cases, LED light transmitted through the light polarizer is linearly polarized and/or circularly polarized (e.g., left or right).

Light polarizers may comprise numerous components, according to some embodiments. Common light polarizers are known to those of ordinary skill in the art, such as light polarizing films and/or layers. For example, in some cases, light polarizers such as linear polarizers may be used to linearly polarize light emitted from the LEDs. In some embodiments, light polarizers may comprise a linear polarizer and/or a quarter wave plate (i.e., a retarder). In some such embodiments, the linear polarizer and the quarter wave plate may be configured together to circularly polarize light from the LEDs, e.g., to left or right circularly polarize light. In some embodiments, the light polarizer may comprise a linear polarizer, an adhesive layer, and a quarter wave plate. Additional and/or other components of the light polarizer are possible, such as protective layers, which may protect and/or increase the robustness of the light polarizer.

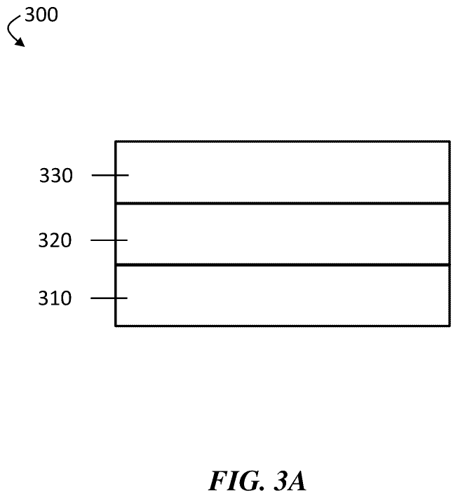

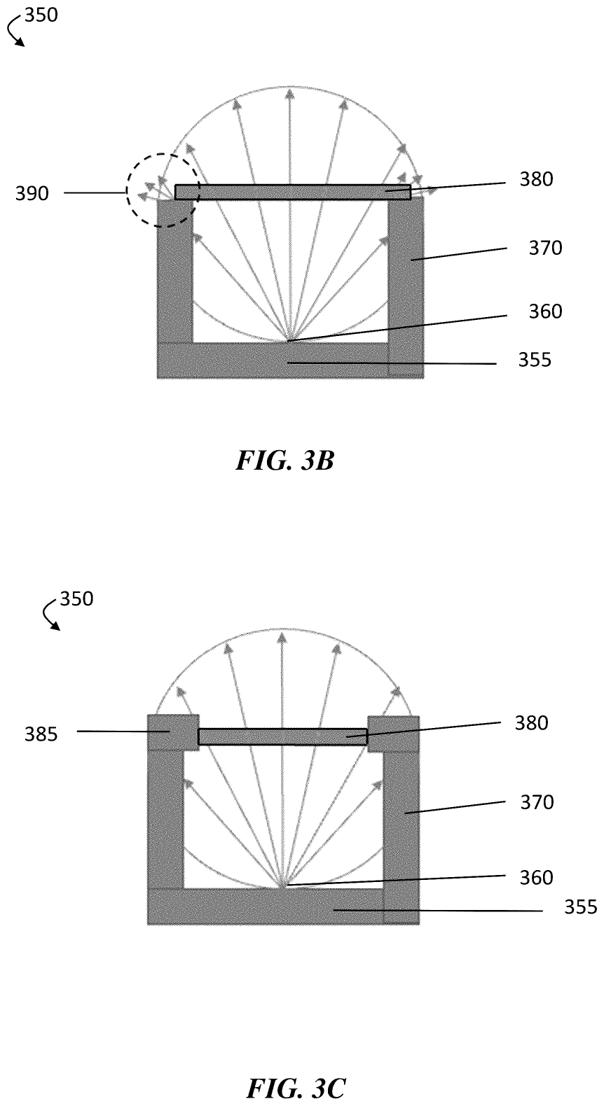

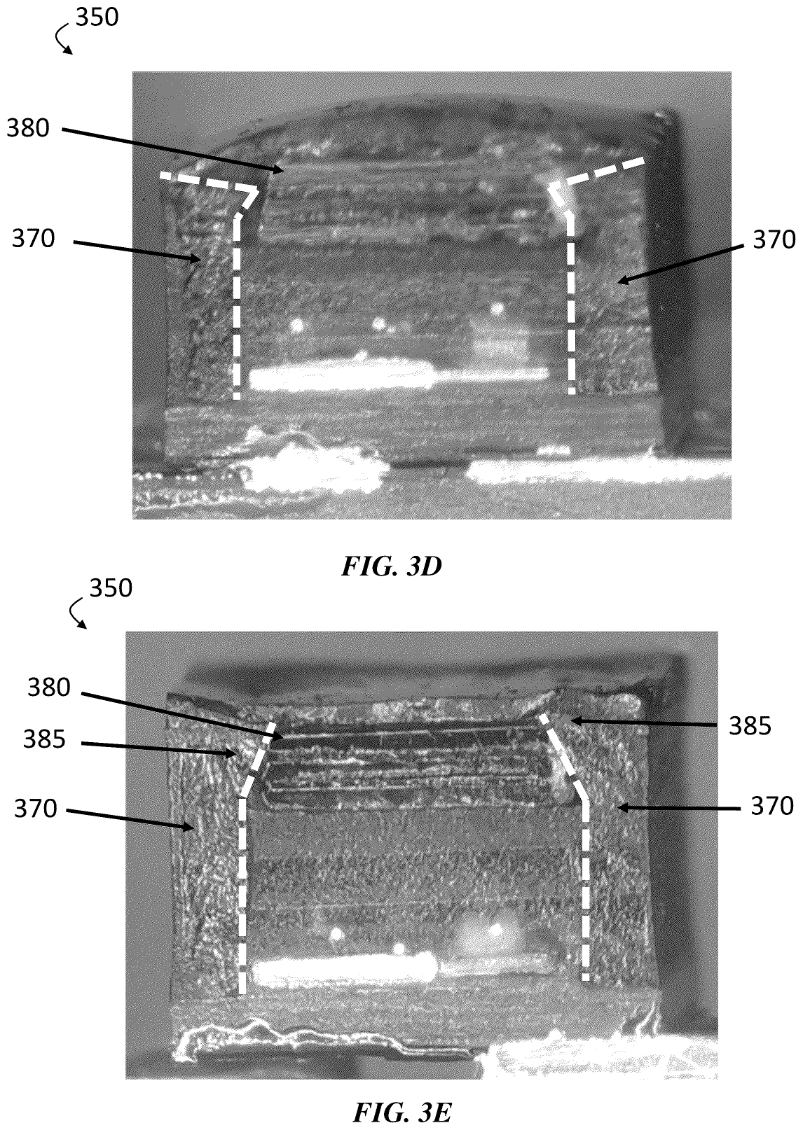

FIG. 3A shows an illustrative diagram of the structure of some light polarizers 300. In this exemplary embodiment, light polarizer 300 comprises three layers and is configured to circularly polarize light. From the bottom, the first layer 310 comprises a linear polarizer, the second layer 320 comprises an adhesive, and the third layer 330 comprises a quarter wave plate. While illustrated in FIG. 3A as layers with equal thicknesses, the dimensions of each layer within the light polarizer 300 are not necessarily uniform. In other embodiments, other structures, orientations, and elements within the light polarizer are possible, as this disclosure is not so limited. Additionally, note that the quarter wave plate 330, in combination with the linear polarizer 310, is configured to circularly polarize light transmitted through the light polarizer 300. According to one set of embodiments wherein there are a plurality of LED packages comprising a plurality of light polarizers 300, the light polarizer for some pixels may be configured to right circular polarize light, whereas the light polarizer for other pixels may be configured to left circular polarize light. That is, in some cases, it may be advantageous to use pixels (e.g., LED packages) comprising light polarizers that polarize light differently, which is discussed in more detail elsewhere herein.

In some cases, the light polarizer is placed in at least a portion of the optical path of the LED light, and in this manner, light that passes through the light polarizer is polarized (e.g., linearly and/or circularly). According to some embodiments, a side wall material may be dispensed to surround each pixel (e.g., LED package) as discussed in more detail next, such that most and/or all of the light that does not pass through the light polarizer is not emitted from the pixel.

While the light polarizers may polarize the light emitted from LEDs, in some cases, the light polarizer may also limit the brightness of the light emitted from each pixel (e.g., after passing through the light polarizer). While in some cases (e.g., in dark rooms), limited brightness from each pixel may not be an issue, in some embodiments, the limited brightness may detract from overall image quality (e.g., brightness and/or luminous intensity) and/or contrast ratio between the pixels. Accordingly, in some cases, relatively large LEDs may be used to increase the brightness of each pixel, despite the resolution lost in the resulting LED display.

As mentioned above, each pixel (e.g., LED package) of the LED display may comprise a side wall material which forms a side wall for each pixel. The side wall may extend vertically from the substrate. The side wall may extend vertically from the substrate and include an overhanging structure, in some cases. According to some embodiments, a first side of the side wall is in contact with respective sides of the intervening layer, the adhesive layer, and the light polarizer, and a second side of the side wall may be exposed to atmosphere. In accordance with some embodiments, the side wall material may fill space present between adjacent LED packages (e.g., the space present before introduction of the side wall material) such that the side wall material contacts more than one LED package. For instance, in some embodiments, the side wall is in contact with respective sides of the intervening layer, adhesive layer, and the light polarizer of a first and a second LED package, where the first and second LED packages are adjacent to each other. In some such embodiments, the side wall material may be in contact with respective sides of the intervening layer, the adhesive layer, and the light polarizer of a third LED package, a fourth LED package, and so forth, until most (e.g., greater than or equal to 90%, 95%, 99%) and/or all of the LED packages of a LED display are contacted with the side wall material. For example, consider FIG. 2H, which is a schematic diagram of a top-down view of a plurality of LED packages 250, where each LED package 250 is surrounded by side wall material 280. In accordance with some embodiments, arranging a side wall material between LED packages may improve the contrast ratio of (e.g. circularly polarized) light emitted from an LED display comprising the LED packages. For instance, the side wall material may absorb some and/or all light emitted from the LED dies that is not directed towards the light polarizer (e.g., to be polarized when passing therethrough) and/or stray light that does not pass through the light polarizer.

Introducing a side wall may be advantageous for a number of reasons. For example, the side wall may be optically opaque, or at least partially opaque, thereby preventing the transmission of light from one pixel from interfering with another pixel. In such a manner, the side wall minimizes the amount of stray light between pixels, which may improve contrast ratio between pixels. According to some embodiments, a side wall may also be useful for minimizing the amount of light emitted from the LEDs of each pixel that does not pass through the light polarizer (and thus is not polarized by the light polarizer) of each pixel. Limiting the amount of light emitted from each LED pixel that does not pass through the light polarizer may further improve contrast ratios of pixels and/or improve the overall image quality (e.g., resolution) from the plurality of pixels. In some embodiments, introducing a side wall material between adjacent LED packages may be easier than introducing a different element between the LED dies of adjacent LED packages (e.g., such as a mirror), which may allow for relatively easy fabrication of the LED display comprising the side wall material in contrast to LED displays with different elements.

The side wall material is generally dispensed such that it forms a perimeter around each pixel, in accordance with some embodiments. In other words, in some cases, each pixel may be surrounded by a side wall. However, the surface above the LEDs (e.g., opposite the substrate) and below the LEDs (e.g., the substrate) is not completely surrounded by the side walls, in accordance with some embodiments.

In some cases, the side walls may have a height such that it completely surrounds the perimeter of the light polarizer. In some cases, the height of the side walls may be greater than or equal to 0.1 mm. In some cases, the height of the side walls may be less than or equal to 2 mm. Combinations of the foregoing ranges are possible. Advantageously, surrounding the complete perimeter of the light polarizer associated with a LED package may minimize stray light emitted from the LED package, which may facilitate higher contrast ratios. In some embodiments, the side wall may include an overhanging structure (e.g., an overhanging portion) as described in more detail elsewhere herein, which may further desirably reduce the amount of stray light emitted from each LED package.

According to some cases, the side wall material may be over-dispensed such that the side wall comprises an overhanging structure, as described earlier as element 285 in FIG. 2E. The overhanging structure may be formed over and/or formed directly on at least a section of the light polarizer and may be configured to minimize and/or eliminate light emitted from the LEDs of each pixel that does not pass through the light polarizer, according to some cases. In some embodiments, the overhanging structure may be in close proximity with the edge of the light polarizer. According to some embodiments, the side wall and/or the overhanging structure may be configured to surround the entire edge of the light polarizer so that substantially no stray light is emitted from the edges of the light polarizer. As generally described elsewhere herein, in one set of embodiments when the LED is a Lambertian emitter, the side walls and/or the overhanging structure may reduce or eliminate stray light from being emitted from the LED package. In some cases, the overhanging structure that is formed over and/or directly on the light polarizer may be physically supported by the light polarizer and/or other underlying layers. In another set of embodiments, the LEDs may not be Lambertian emitters.

FIGS. 3B-C are schematic diagrams illustrating the usefulness of the overhanging structure in the LED package when present and wherein the LED is a Lambertian emitter. Note that, in these examples, the LED is located centrally relative to the side walls. In other embodiments, the position of the LED may vary and may change how the light emitted from the LED interacts with the side walls and/or overhanging structure. FIG. 3B shows an exemplary LED package 350 comprising substrate 355, LED 360 with arrows displaying the direction in which light is emitted, side walls 370, and light polarizer 380. In this example, side walls 370 are not over-dispensed, and thus are not formed on or formed over the light polarizer 380. As a result, stray light may leak from the edge of the light polarizer 380 (e.g., the light is refracted, the light is not polarized, etc.), as outlined in the dotted circle 390. The stray light outlined in circle 390 may be emitted in a direction that is not substantially perpendicular to the plane of substrate 355 (e.g., and thus may lead to cross talk between adjacent LED packages) and/or may not be polarized in the same manner as light that transmits entirely through light polarizer 380. FIG. 3C is an illustration of an alternative embodiment to FIG. 3B, wherein LED package 350 comprising substrate 355, LED 360 with arrows indicating the direction in which light is emitted, side walls 370, light polarizer 380, and an overhanging structure 385. In this case, because the overhanging structure 385 rises above the edge of light polarizer 380, no light is leaked from the edge of the light polarizer 380. As described elsewhere herein, minimizing and/or eliminating stray light may improve the contrast ratio of the light emitted from the LED package.

FIGS. 3D-E are optical micrographs, corresponding to the schematic illustrations of FIGS. 3B-C, that show cross sectional images of exemplary embodiments of LED packages with and without the overhanging structure. For example, in FIG. 3D, LED package 350 comprising side wall 370 (outlined with the dashed white lines) and the light polarizer 380. In this case, the side wall 370 was not over-dispensed and does not rise above to form over and/or form directly on the light polarizer 380. Accordingly, stray light may leak from the edges of the light polarizer 380, as illustrated in FIG. 3B, and may lower the contrast ratio of the light emitted from the LED package 350. In FIG. 3E, LED package 350 comprises side wall 370 (again outlined by the dashed white line), light polarizer 380, and overhanging structure 385. As mentioned elsewhere herein, the side walls 370 include the overhanging structure 385. The overhanging structure functions to eliminate stray light from emitted from the light polarizer 380, as described above in the context of FIG. 3C, which may improve the contrast ratio of the light emitted from the LED package 350.

According to some embodiments, the overhanging portion of the side wall extends over the section of the light polarizer. For example, in some cases, the overhanging structure may cover greater than or equal to 0.1%, greater than or equal to 0.2%, greater than or equal to 0.3%, greater than or equal to 0.5%, greater than or equal to 0.8%, greater than or equal to 1%, greater than or equal to 1.5%, greater than or equal to 2%, greater than or equal to 3%, greater than or equal to 4%, greater than or equal to 5%, greater than or equal to 6%, greater than or equal to 8%, or greater than or equal to 10% of the surface area or the light polarizer. According to some embodiments, the overhanging structure may cover less than or equal to 10%, less than or equal to 8%, less than or equal to 6%, less than or equal to 5%, less than or equal to 4%, less than or equal to 3%, less than or equal to 2%, less than or equal to 1.5%, less than or equal to 1%, less than or equal to 0.8%, less than or equal to 0.5%, less than or equal to 0.3%, less than or equal to 0.2%, or less than or equal to 0.1% of the surface area or the light polarizer. Combinations of the foregoing ranges are possible (e.g., greater than or equal to 0.1% and less than or equal to 10%). Other ranges are also possible.

Any of a variety of suitable materials for the side walls are possible. As described above, the side wall material is generally at least partially opaque, and ideally fully opaque. Opaque is to take its general meaning in the art, generally indicating that light does not transmit through the material and is instead absorbed and/or reflected by the material. That is, in some cases, the side wall may have a transmittance, for example, of less than or equal to 0.3 or less than or equal to 0.1. The side walls may comprise exemplary materials such as carbon black powder, black dyes (e.g., BM-01-90), polyphthalamide (PPA), polycyclohexylene-dimethylene terephthalates (PCT), and/or epoxies (e.g., epoxy molding compound). In some such cases, an adhesive material (e.g., an epoxy) in which a light absorbing material (e.g., carbon black powders and/or black dyes) is distributed may be used. For example, in some such cases, the amount of light absorbing material present in the side wall is greater than or equal to 5 wt % and less than or equal to 30 wt % of the side wall material, with the balance being an adhesive. The side wall material may be a single material. According to some embodiments, the side wall material maybe a mixture of precursors, for example, two precursors, three precursors, four precursors, and so forth. In some such cases, the precursors of the side wall material may be dispensed using a multi-plunger syringe, wherein the precursors are mixed during the dispensing and then cured to form the side wall material. It may be particularly advantageous to use a side wall material comprising black dye that is relatively optically opaque and an adhesive epoxy (e.g., epoxy 255ABCD with a ratio of 9:8:3.6:1) to maintain the structure of the side walls. Other side wall materials are also possible.

Curing the side wall materials may be done by heating the side wall precursors after mixing. In general, the side wall materials are cured at suitable temperatures and times.

After curing the side wall material and singulating the pixels as described elsewhere herein, in some cases, the thickness of the side wall may be greater than or equal to 10 microns, greater than or equal to 100 microns, greater than or equal to 250 microns, greater than or equal to 500 microns, greater than or equal to 750 microns, or greater than or equal to 1 mm. In some embodiments, the thickness of the side wall may be, less than or equal to 1 mm, less than or equal to 750 microns, less than or equal to 500 microns, less than or equal to 250 microns, less than or equal to 100 microns, or less than or equal to 10 microns. Combinations of the foregoing ranges are possible (e.g., greater than or equal to 10 microns and less than or equal to 100 microns). Other ranges are also possible. In some embodiments, after curing the side wall material, no singulation of the LED packages occur, and the side wall material may have a suitable thickness such that it fills substantially all of the space between adjacent LED packages. A nonlimiting example of a plurality of LED packages 250 with side wall material 280 filling substantially all of the space therebetween is shown in FIG. 2H.

In some cases, each pixel (e.g., LED package) may further comprise an optical resin cap, wherein the optical resin cap is above and in contact with the light polarizer. According to some embodiments, the optical resin cap may be formed over and/or formed directly on the light polarizer. The optical resin cap may have a number of purposes, including protecting the light polarizers and/or underlying layers. In some cases, because the optical resin cap may be relatively robust, it is accordingly relatively resistant to scratching, abrasion, weathering, and/or other forms of degrading. The robustness of the optical resin cap allows the optical resin cap to provide protection to any underlying layers (e.g., the polarizing films) and prevent damage to the underlying layers, according to some embodiments, which may extend the lifetime of the LED package. The robustness of the optical resin cap is described in more detail later herein.

In addition to being robust, in some cases, the optical resin cap may comprise other properties. For example, the optical resin cap, according to some embodiments, may be optically clear and/or have a relatively low birefringence in order to avoid disrupting the emission of the light from the LED package and/or the polarization of the light after it passes through the light polarizer. In some embodiments, to avoid disruption of the circular polarization of the light that passes through the light polarizer, the optical resin cap is greater than or equal to 15 microns or greater than or equal to 40 microns thick. In some cases, the optical resin cap is less than or equal to 40 microns. Other ranges are also possible.

According to some embodiments, a side wall material may be dispensed to surround each pixel such that any light that does not pass through the light polarizer is absorbed by the side wall material and thus does not pass through the optical resin cap and subsequently emit from the pixel.

The optical resin cap may comprise any of a number of suitable materials. In some cases, the optical resin maybe a single material. According to some embodiments, the optical resin cap may be a mixture of precursors, for example two precursors, three precursors, four precursors, and so forth. In some such cases, the precursors of the optical resin cap may be dispensed using a multi-plunger syringe, wherein the precursors are mixed during the dispensing and then cured to form the optical resin cap. Other optical resin caps are also possible.

As illustrated in the exemplary schematic diagram of FIG. 1, the optical resin cap may be dispensed such that it is relatively convex layer. According to some embodiments, the optical resin cap may be dispensed such that it forms a relatively concave layer. In some cases, the optical resin cap may be dispensed such that it forms a uniform, relatively flat layer (e.g., not substantially convex or concave). The dispensing of the optical resin cap and subsequently achieved architecture of the optical resin cap may be selected in accordance with the desired optical properties of the final goal of the LED package.

In some embodiments, in place of the optical resin cap, other layers and/or lens may be placed over and/or placed directly on the light polarizer. The other layers and/or lens may provide similar advantages to an optical resin cap such as, for example, protecting the light polarizer. In some such cases, however, the other layer and/or layer may not be formed in-situ, e.g., on the pixel. In contrast, the other layer and/or lens may be formed ex-situ (e.g., not in-situ, not over and/or not directly on the light polarizer) and then placed over and/or placed on the light polarizer. According to some embodiments, a protective layer may be formed over the light polarizer of the LED package, i.e., instead of an optical resin cap. Some aspects are related to LED displays comprising a plurality of LED packages, where a protective layer may be formed over the plurality of LED packages. In some embodiments, a single protective layer may be formed over the plurality of LED packages such that the single protective layer is formed over each of the LED packages. In some embodiments, a single protective layer may be more easily processed, e.g., compared to a plurality of optical resins (e.g., discrete amounts of resin, optical resin caps on each LED package) being present over a respective plurality of LED packages as in other embodiments described herein. The protective layer, in some such cases, may be formed in-situ or ex-situ. In some embodiments, the protective layer may be formed such that a top surface of the protective layer is substantially parallel to a top surface at least some, and in some cases all, of the top surfaces of the LED packages over which the protective layer is formed. In some embodiments, the top surface of the protective layer is substantially flat. In some embodiments, the protective layer is formed such that a top surface of the protective layer is convex. In some embodiments, the protective layer is formed such that a top surface of the protective layer is concave.

The present disclosure is generally related to LED packages comprising multiple layers and/or components (e.g., substrate, LED dies, intervening layer, adhesive layer, light polarizer, optical resin cap, and/or side walls including an overhanging structure), as described in the exemplary embodiment of FIG. 1. Layers may be formed directly on each other, in some cases. According to some such embodiments, a first layer may be present in the LED package with a second layer formed thereon. Forming directly on generally refers to when the second layer is in physical contact and at least partially above the first layer. As a non-limiting example, in FIG. 1, the adhesive layer 150 is formed directly on the intervening layer 140.

In some cases, a second layer may be formed over a first layer. Forming over is similar to being formed directly on, generally indicating the second layer is above the first layer, but differs in that it does not necessarily mean that the layers are in physical contact with each other. For instance, in some cases, a first layer may be formed over a second layer wherein there is a third layer therebetween the first and second layer. A non-limiting example of one layer formed over other layers can be seen in FIG. 1, wherein the light polarizer 160 is formed over both the adhesive layer 150 and the intervening layer 140. Note that, in this case, light polarizer 160 and intervening layer 140 are not in physical contact due to the presence of the adhesive layer 150, but light polarizer 160 remains formed over intervening layer 140. In contrast, light polarizer 160 and adhesive layer 150 are in physical contact, so light polarizer 160 is both formed over and formed directly on adhesive layer 150.

According to some embodiments, some and/or all of the layers may be index matched. Index matching is to take its ordinary meaning in the art, generally referring to when two or more materials have similar indices of refraction such that when light is transmitted through the two or more materials, there is little-to-no internal reflection and/or internal refraction. Thus, most of the light is transmitted through the layers without being reflected or refracted at the layer interfaces. In some cases, for example, layers formed on and/or over the light polarizer (e.g., a light polarizing film) may be index matched with the light polarizer such that light that transmitted through the light polarizer is polarized and then proceeds through the above layers with little-to-no impact on the polarization of the light.

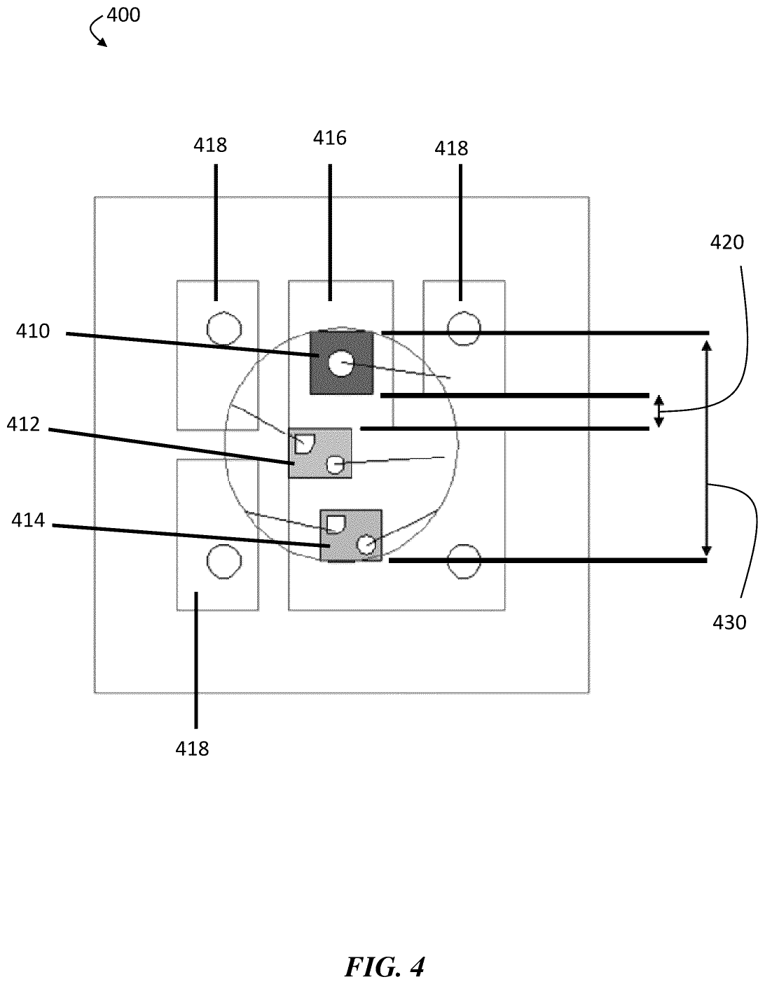

Each pixel within an LED display may comprise at least one red LED, at least one green LED, and at least one blue LED, in accordance with some embodiments. In some cases, the at least three LEDs in each pixel (be at least one red LED, the least one green LED, and the least one blue LED) are arranged in a straight line. In some embodiments, the at least three LEDs are arranged in a triangular orientation, as illustrated in the exemplary pixel 400 in FIG. 4.

In FIG. 4, LEDs 410, 412, and 414 share a common cathode 416 and are each electrically connected to separate anodes 418 so as to be individually controlled. The LEDs in each pixel are spaced as shown, with an inner spacing between the pixels 420 and an outer distance between the edges of the furthest spaced LEDs 430.

The inner spacing between the LEDs (e.g., element 420 in FIG. 4), whether the LEDs are arranged as shown in FIG. 4 or in other arrangements, may vary in accordance with a variety of embodiments. Additionally, the position of the LEDs on the substrate of the pixel may impact how the light interacts with the side walls, the overhanging structure if present, and/or how the light is emitted from the LED package (e.g., due to a Lambertian distribution of the light emitted from the LEDs).

As described elsewhere herein, the complete LED package may comprise a plurality of pixels with various components including a light polarizer, wherein the light polarizer of each pixel polarizes the emitted light from the LEDs and thus the light emitted from the pixel. The LED package maybe constructed such that every other pixel emits left circular polarized light and the remaining pixels emit right circular polarized light. For example, see FIG. 5, which is an illustration of an arrangement of a plurality of pixels 500. Some pixels are configured to emit left circular polarized light (e.g., with a first type of light polarizer), such as pixel 510, whereas the remaining pixels are configured to emit right circular polarized light (e.g., with a second type of light polarizer), such as pixel 520. Using LED packages with pixels arranged to emit left and right circular polarized light in a periodic array as shown in FIG. 5 may be useful, for example, for creating 3D images when viewing the LED package. Note that while the exemplary plurality of pixels shown in FIG. 5 comprises 16 pixels, different numbers of pixels for the plurality of pixels are contemplated as outlined elsewhere herein. Additionally, a plurality of pixels comprising more than 16 pixels may still embody the arrangement of pixels regarding the light polarization (e.g., left circular polarization, right circular polarization, left circular polarization, right circular polarization, and so forth), but expanded over the entirety of the plurality of pixels. Other arrangements of pixels (e.g., the polarization of the light emitted by each pixel) are also possible.

Any of a variety of substrates (e.g., circuit boards) and LED dies are suitable for use in the LED packages described herein, and those of ordinary skill in the art will be able to select appropriate substrates and LED dies. In an exemplary embodiment, an RGB 1515 5065-A2 (0.62) printed circuit board and S-08R1SUZ/S-08HGAUD-C/S-08HBAUD-C 8 mils LED dies may be used. In one set of embodiments, the LED dies may be Lambertian emitters. According to some such embodiments, the height of the side walls and/or the amount of the light polarizer that is covered by the overhanging structure may impact the contrast ratio and/or brightness of the emitted light. The height of the side walls and/or amount of the overhanging structure present that is formed over the light polarizer, in some cases, may be designed in order to maintain the integrity of the light emitted from the LED package. For example, in some embodiments, the sides walls and/or overhanging structure may be designed to improve contrast ratio (e.g., by minimizing stray light). In another set of embodiments, the LED dies may not be Lambertian emitters.

The power output of each LED from each pixel of the LED package may vary. In some cases, the power output of each LED is greater than or equal to 0.1 mW, greater than or equal to 1 mW, greater than or equal to 10 mW, or greater than or equal to 50 mW. According to some embodiments, the power output of each LED is less than or equal to 75 mW, less than or equal to 25 mW, less than or equal to 10 mW, or less than or equal to 1 mW. Combinations of the foregoing ranges are possible. Variations based on the type of LED (e.g., red LED vs blue LED vs green LED) are possible.

The luminous intensity output of each LED from each pixel the LED package may also vary. In some cases, the luminous intensity value of each LED is greater than or equal to 10 mcd, greater than or equal to 100 mcd, or greater than or equal to 200 mcd. In some cases, the luminous intensity value of each LED is less than or equal to 250 mcd, less than or equal to 150 mcd, or less than or equal to 50 mcd. Combinations of the foregoing ranges are possible. Variations based on the type of LED (e.g., red LED vs blue LED vs green LED) are possible.

As discussed above, LED packages may be constructed such that the light emitted from every other pixel is left circularly polarized and the light emitted from the remaining pixels is right circularly polarized. In some cases, like creating 3D images when viewing the LED package, it may be useful to obtain high contrast ratios for each pixel between the left circular polarized light in the right circular polarized light. That is, the ratio of the intensity of light that is left circular polarized divided by the intensity of light that is right circular polarized emitted from each pixel. Relatively high contrast ratios may be obtained, for example, by minimizing and/or eliminating stray light that emits from the LED package. In some LED packages configured to emit left circular polarized light, the contrast ratio of right-to-left circular polarized light maybe greater than or equal to 1 to 50, greater than or equal to 1 to 75, greater than or equal to 1 to 100, greater than or equal to 1 to 125, or greater than or equal to 1 to 150, and/or less than or equal to 1 to 200, less than or equal to 1 to 250, and/or less than or equal to 1 to 300. Combinations of the foregoing ranges are possible. Contrast ratios for left-to-right circular polarized light for LED packages configured to emit right circular polarized light may be similar, according to some embodiments.

Relatively high values for contrast ratios as described above for each pixel (e.g., LED package) may provide high quality images from the LED packages. In some such cases, the high contrast ratios between right and left polarized light may provide advantages when creating certain types of images, for example, 3D images with 3D polarized glasses. For instance, in some cases, it may be advantageous to have a contrast ratio of greater than or equal to 1 to 150 for the LED packages to exhibit cinema-grade performance.

The LED displays comprising the LED packages described herein, in some embodiments, may be relatively large LED displays. In some embodiments, the LED displays described herein may be used to generate large 3-D images, for instance. In industrial applications. As a non-limiting example, the LED displays described herein may be used in a cinema. In some embodiments, the LED displays may generate 3-D images as an electronic billboard. Accordingly, in some embodiments, the LED displays are configured to be used outdoors.

In some embodiments, a substrate may be provided with a plurality of LED arrays in electrical communication with the substrate. The LED arrays may comprise a red, blue, and green LED die. For instance, each red, blue, and green LED die of each LED package may be in electrical communication with the substrate. The intervening layer on top of the substrate and/or the LEDs may be formed in a variety of suitable methods, in accordance with some embodiments. In some cases, the intervening layer may be formed over and/or formed directly on top of the substrate and/or the LEDs. A non-limiting example of the intervening layer formed over the LEDs and the substrate is shown in FIG. 2B. In some embodiments, the intervening layer is applied by using a dual pump syringe. That is, in some cases, two precursors may be dispensed using a dual pump syringe on top of the substrate, wherein upon contact of the two precursors and/or following a curing step (e.g., heating), the two precursors may cross link to form the material of the intervening layer. In some embodiments, the two precursors may cross link to form a silicone. In some cases, it may be advantageous to use a material that is a liquid and then cures to form a solid to form an intervening layer that is relatively flat as described elsewhere herein.

After applying the intervening layer above the substrate and/or the LEDs, an adhesive layer may be formed over and/or formed directly on the intervening layer to facilitate attaching the light polarizer to the intervening layer. FIG. 2C shows a non-limiting example of the adhesive layer formed over the intervening layer. Any of a number of adhesives are possible and may be placed on the intervening layer in any of a variety of possible methods. For example, an adhesive may be placed on the intervening layer, dispensed from a syringe on to the intervening layer, or precursors comprising the adhesive may be mixed and dispensed on to the intervening layer. Other methods for adding the adhesive to the intervening layer are also possible. Non-limiting examples of adhesives include glues, epoxies, silicones, and tapes. Other adhesives are also possible, as this disclosure is not so limited. In some cases, it may be useful to use a liquid adhesive (e.g., a silicone that is subsequently cured) to maintain a relatively flat layer on which the light polarizer and/or other layers may be applied.

After applying (e.g., forming, dispensing, and/or curing) the intervening layer and the adhesive layer on top of the substrate and/or the LEDs, according to some embodiments, at least the intervening layer and the adhesive layer of the plurality of pixels may be cut between the LED arrays in order to separate the pixels (e.g., each LED array) of the plurality of pixels. Separating the pixels may be achieved by a number of suitable cutting methods, such as conventional cutting methods (e.g., using a semiconductor dicing saw and/or LED saw), IR laser cutting, and/or UV laser cutting. It may be particularly advantageous to use a conventional cutting method under wet conditions (e.g., in a solvent) to separate the pixels. As described above, separating the pixels will result in a space between the intervening layers of each of the pixels, as illustrated as element 260 in FIG. 2C.

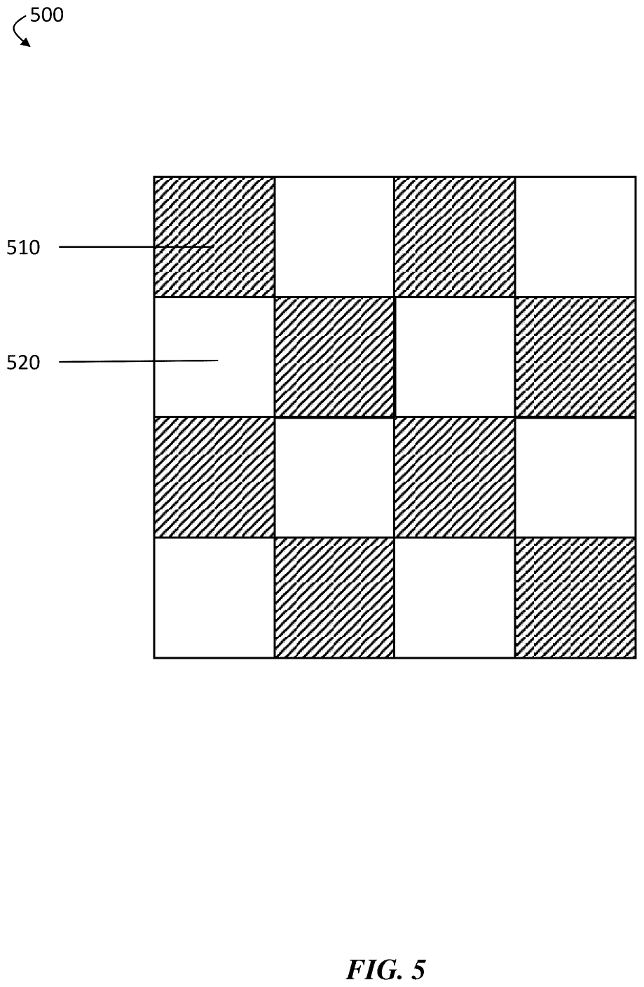

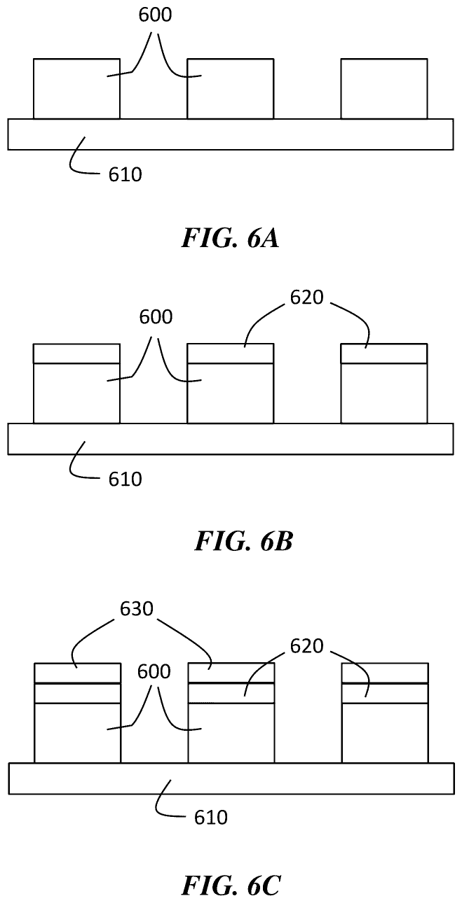

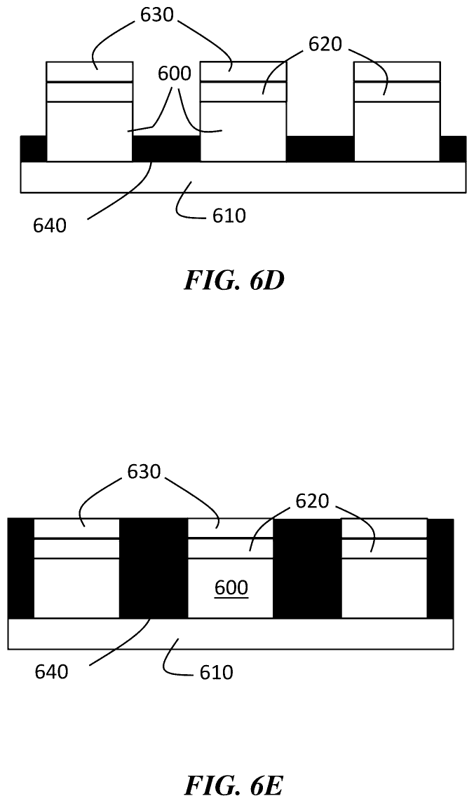

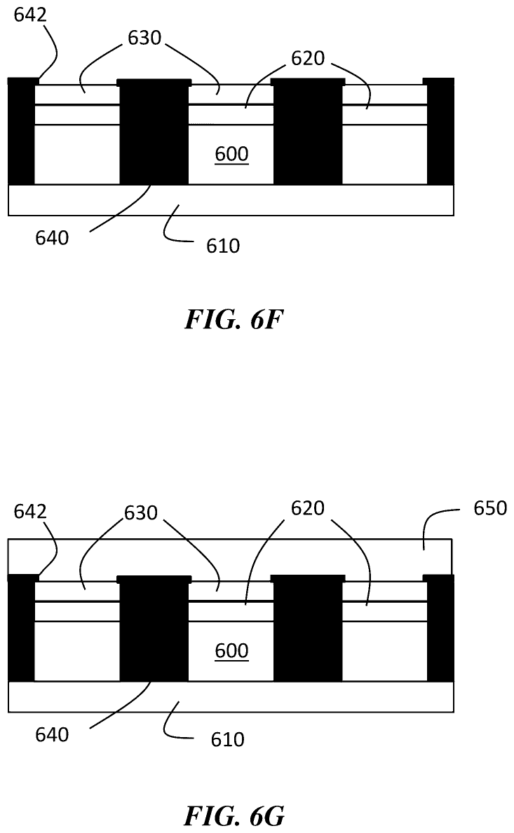

In some embodiments, the method may include providing a plurality of LED packages. Each LED package, in some such embodiments, may include a red LED die in electrical communication with a substrate, a green LED die in electrical communication with the substrate, a blue LED die in electrical communication with the substrate, and an intervening layer formed over each of the LED dies. For example, FIG. 6A shows a plurality of LED packages 600 disposed on a substrate 610, where each of the LED packages comprises a red LED die in electrical communication with a substrate, a green LED die in electrical communication with the substrate, a blue LED die in electrical communication with the substrate, and an intervening layer formed over each of the LED dies. Accordingly, in some embodiments, the plurality of LED packages may be provided. Providing the plurality of LED packages may comprise purchasing a commercially available LED package, e.g., configured to emit unpolarized light. In other embodiments, as described above, a substrate may be provided with a plurality of LED arrays in electrical communication with the substrate. In some embodiments where the plurality of LED packages is provided, the intervening layer of each LED package may be provided and each LED package may be separated (e.g., no need to singulate the intervening layer, in some embodiments) when initially provided. According to some such embodiments, adjacent LED packages of the plurality of LED packages may include a space therebetween (e.g., between the intervening layer of each LED package). Providing the plurality of LED packages, in some embodiments, may desirably increase the speed of producing an LED display comprising light polarizers as described herein, e.g., when compared to other embodiments where the plurality of LED packages may be constructed from a substrate including LED dies (e.g., without the intervening layer present and/or individual LED packages pre-formed thereon).

According to some embodiments, an adhesive layer may be formed over the intervening layer of each LED package (e.g., of a provided and/or fabricated LED package). It will be understood that respective adhesive layers may be formed over each of the LED packages (e.g., a first adhesive layer formed over a first intervening layer of a first LED package, a second adhesive layer formed over a second intervening layer of a second LED package, and so forth for the plurality of LED packages). Forming an adhesive layer over each of the LED packages, in accordance with some embodiments, may desirably facilitate placement of individual light polarizers over each of the LED packages.

The light polarizer may be cut before being attached to each pixel (e.g., LED package). Accordingly, in some embodiments, the method may include pre-cutting the light polarizer, e.g., before placing the light polarizer over an LED package. A plurality of light polarizers may be pre-cut before being positioned and/or placed over a respective plurality of LED packages. This may be done for a number of reasons. For example, in some cases, the light polarizers are not compatible with conventional wet-cutting methods. That is, in some cases, the light polarizer may not be compatible with being cut via a wet cutting method because the solvent used may degrade and/or delaminate portions of the light polarizer, thereby lowering the quality of light polarization achieved by the light polarizer. Additionally, as described above, in some cases, it may be advantageous to use different light polarizers that polarize the light emitted from separate pixels in another way (e.g., left or right circular polarized light). That is, to achieve LED packages comprising a plurality of pixels arranged to emit light as illustrated in FIG. 5, the light polarizer may be precut before attaching it to the LED package.

The light polarizer may be pre-cut into a plurality of light polarizers, wherein each light polarizer is appropriately sized to be positioned on a single pixel and to cover at least a section of the optical path of the light emitted from the LEDs of each pixel. In some embodiments, the light polarizer on each pixel is pre-cut to a size and positioned such that it covers the whole optical path of the light emitted from the LED packages (e.g., light is not emitted from the LED package through the side walls and/or substrate). According to some embodiments, the light polarizers are pre-cut such that the dimensions of the cut light polarizer may be substantially the same as to the dimensions of a top surface of each of the LED packages. In some embodiments, the light polarizers are pre-cut such that the dimensions of the cut light polarizer may be larger when compared to the dimensions of a top surface of each of the LED packages. For example, each dimension (e.g., length or width) of the cut light polarizer may be greater than or equal to 1%, greater than or equal to 5%, greater than or equal to 10%, and/or less than or equal to 20%, or less than or equal to 30% larger than a corresponding dimension of an LED package on which the cut light polarizer may be positioned. Advantageously, using a cut light polarizer that is at least substantially similar in size, and in some cases larger, to a top surface of a corresponding LED package may prevent light being transmitted from the LED package through the surface on which the light polarizer is positioned without passing through the light polarizer. As a non-limiting embodiment, an LED package may be 1 mm by 1 mm when viewed from above (e.g., length by width). In some such embodiments, a light polarizer to be positioned above the LED package and may be pre-cut such that it has dimensions (e.g., length and/or width) that are greater than or equal to 1 mm and less than or equal to 1.3 mm. Other sizes are also possible, and may be selected based on the corresponding size of the LED package.

In some cases, each light polarizer is positioned on the top surface (e.g., the top plane of the LED package that is substantially parallel to the substrate) of the adhesive layer, as shown in FIG. 2D, to polarize any light emitted in a direction perpendicular to the plane of the substrate. The light polarizer may be pre-cut using a variety of methods, including UV laser cutting, IR laser cutting, or physical cutting. It may be particularly advantageous to laser cut the light polarizer using a UV laser to avoid burring of the light polarizer. Cutting the light polarizer may impact the shape of the light polarizer (e.g., at the edges), so steps should be taken to ensure that the film is uniformly cut to avoid issues after cutting the light polarizer.

Any of a variety of shapes and sizes for the cut light polarizer are possible. In some cases, it may be useful to cut the light polarizer into a square shape to correspond to the pixel (e.g., in cases where the pixels are square shaped). Other shapes for the light polarizers are also possible, such as triangular, other polygon shapes, and irregular shapes. The size of the light polarizer may vary to correspond to the size of the pixel.

The light polarizers may be individually placed on to each pixel (e.g., each LED package of a plurality of LED packages), in accordance with some embodiments, such that a single light polarizer is placed over the adhesive layer of each LED package. Accordingly, in some embodiments, the method may include placing a respective light polarizer over each of the LED packages. Accordingly, in some embodiments, the method may include positioning a respective light polarizer over each of the LED packages. In some embodiments, the light polarizer may be positioned and/or placed to polarize light emitted from the LED packages. According to some embodiments, a plurality of light polarizers may be positioned and/or placed over respective LED packages (e.g., a first light polarizer over a first LED package, a second light polarizer over a second LED package, etc.) and arranged to circularly polarize light, e.g., as shown in FIG. 5. In some cases, the precut light polarizers are placed manually. According to some embodiments, it may be advantageous to use a pick-and-place machine to place the light polarizer on each pixel. When compared to previous manufacturing techniques for conventional LED displays, individually placing the light polarizers on each pixel may facilitate and/or may streamline arranging the plurality of pixels to emit light as shown in FIG. 5, in some cases. Moreover, in some embodiments, individually placing the light polarizers on each pixel of the LED display may facilitate the integration of the light polarizers into each LED package. Placement and/or integration of respective light polarizers into each of the LED packages, in some embodiments, may facilitate more compactly formed LED packages and/or the dispensing and/or integration of side wall material between adjacent LED packages. For example, typical LED display constructions for circularly polarized light may use a first film to left circularly polarize light, where the first film is absent over certain LED packages (e.g., every other LED package). A second film may be used to cover the LED packages where the first film is absent. Accordingly, the first and second films may prevent the addition of side wall material between LED packages. Individually placed light polarizers desirably facilitate the integration of such side wall material. The side wall material, in some embodiments and as described in more detail elsewhere herein, may improve contrast ratios of the resulting LED display (e.g., a contrast ratio between left and right circularly polarized light from the LED display) relative to typical LED displays by limiting and/or preventing unpolarized light from being emitted from the LED packages.

When manufacturing the LED package, it may be useful to perform some or all of the steps under a suitable vacuum. In some embodiments, it may be useful to expose the LED package to a vacuum during and/or between manufacturing steps. For example, in some embodiments, the method includes exposing the LED package to a vacuum. In some embodiments, the method includes exposing the plurality of LED packages to a vacuum. According to some embodiments, exposing the LED package to a vacuum at various points during the manufacturing process may improve the performance of the end-product (e.g., the LED package after all the components have been integrated). After forming the intervening layer and the light polarizer over the substrate and/or LEDs, in some cases, exposing the LED package to a vacuum may prove useful. For example, in cases where the intervening layer comprises silicone, wherein the silicone may comprise air bubbles from the adding the silicone precursors, exposure to a vacuum may remove air bubbles from the intervening layer. Removing air bubbles, and as a result making the optical path through the layers more uniform, may improve image quality (e.g., contrast ratio between pixels and/or luminous intensity) from the LED package.

According to some embodiments, a side wall material may be dispensed in the spaces cut between each pixel (e.g., LED package), as shown in FIG. 2E. In some cases, the sidewall material may be over-dispensed purposefully in order to include an overhanging structure. Accordingly, in some embodiments, the method includes forming an overhanging portion of a side wall over at least one LED package. In some embodiments, the method includes forming an overhanging portion of a side wall over each LED package of a plurality of LED packages. The overhanging structure may be present to reduce stray light between the pixels and/or for minimizing the amount of stray light emitted from the pixels that does not pass through the light polarizers.

Dispensing the side wall material to form the sidewalls between the pixels (e.g., LED packages) may be achieved in a variety of suitable methods, in accordance with some embodiments. In some cases, the side wall material and/or its precursors may be dispensed using a syringe. In some embodiments, conventional inkjet technology is used to dispense the side wall material and/or its precursors between the pixels of the LED display. In some embodiments, a single jet may be used to dispense the side wall material between the pixels of an LED display. In some cases, a plurality of jets may be used to dispense the side wall material within an LED display. For instance, a first jet may be used to dispense side wall material between a first and second LED package while a second jet may be used to dispense side wall material between the second and a third LED package, where the first and third LED packages are on opposite sides of the second LED package. There may be a corresponding number of jets to spaces between LED packages of the LED display in order to dispense material therebetween. Accordingly, the method may comprise dispensing the side wall material using one or more inkjets. In some embodiments, the method comprises dispensing the side wall material using a plurality of inkjets. Other methods for dispensing the side wall material and/or its precursors onto the LED package (e.g., around the perimeter of the LED package) are possible. In some embodiments, the method includes dispensing the side wall material between adjacent LED packages, e.g., of a plurality of LED packages. In some embodiments, the side wall material and/or its precursors may be cured after dispensing. The curing of the side wall material may be achieved via heating, exposure to UV light, or any other of a number of suitable methods for curing materials.

In some embodiments, a frame may be inserted between LED packages of a LED display. For instance, the frame may be 3-D printed and/or molded such that it is sized to be positioned and to fill substantially all of the space between adjacent LED packages of an LED display when positioned thereon. Accordingly, in some embodiments, methods may include positioning a frame between the LED packages of an LED display. Following positioning of the frame, a side wall material may be dispensed to fill any remaining space between LED packages and/or to cover at least a portion of the top surface of a light polarizer (e.g., to form an overhanging portion).

An optical resin cap may be applied on top of the light polarizer, in accordance with some of embodiments. Applying the optical resin cap may comprise dispensing the optical resin cap and/or its precursors using a syringe or dual pump syringe (e.g., or multi-pump syringe if more than two precursors). According to some embodiments, it may be advantageous to dispense the amount of optical resin that forms a relatively flat layer, parallel to the intervening layer and light polarizer. In some cases, however, the optical resin is over- or under-dispensed, resulting in a concave top surface or a dome-like meniscus on top of the LED package, respectively. In some embodiments, the method may include forming a protective layer over the LED package. In some embodiments, the method may include forming a protective layer over at least some of a plurality of LED packages. In some embodiments, the method includes forming a protective layer over an entire plurality of LED packages. The protective layer may be optically transparent and/or index matched to one or more of the other layers of the LED packages (e.g., the intervening layer, the adhesive layer, and/or the light polarizer). In some embodiments, only a single protective layer may be formed over the LED package and/or the plurality of LED packages.

Following the dispensing of the optical resin cap, the pixels are singulated (e.g., the side walls are singulated, see FIG. 2G), in some embodiments. Singulation may be performed using conventional cutting methods, IR laser cutting, and/or UV laser cutting. It may be particularly advantageous to use conventional cutting methods (e.g., a semiconductor dicing saw under wet conditions).

According to some embodiments, an LED display may comprise the plurality of pixels (e.g., a plurality of LED packages), wherein each pixel comprises an LED package comprising a substrate, LED dies, intervening layer, adhesive layer, light polarizer, optical resin cap, a protective layer, and/or side walls (e.g., comprising side wall material) optionally including an overhanging structure. The pixels of the LED display may be constructed and/or arranged such that every other pixel is configured to emit left circular polarized light and the remaining pixels are configured to emit right circular polarized light, as illustrated in the exemplary embodiment of FIG. 5. Such a construction and arrangement may be advantageous for emitting circularly polarized light, e.g., for 3-D displays. For instance, in some embodiments, the method may include emitting circularly polarized light from the plurality of LED packages of the LED display. In some such embodiments, a contrast ratio of light emitted from the LED display may be greater than or equal to 1 to 100, 1 to 150, etc., as described elsewhere herein.

FIGS. 6A-6G show schematic diagrams of a non-limiting example of method of making an LED display. Circularly polarized LED displays were made by providing an LED display having a plurality of LED packages 600 on a substrate 610, as shown in FIG. 6A. Each LED package 600 comprises a red, blue, and green LED die with an intervening layer formed thereover. An adhesive layer 620 was formed over each LED package 600, as shown in FIG. 6B, whereafter respective circularly polarized light polarizers 630 were placed over each of the adhesive layers 620 of the plurality of LED packages 600, as illustrated in FIG. 6C. The circularly polarized light polarizers were arranged such that light emitted from adjacent LED packages were alternately left and right circularly polarized, as schematically depicted in FIG. 5. Following placement of the light polarizers, a side wall material was dispensed to varying levels between adjacent LED packages to form a side wall therebetween, as shown in FIGS. 6D-6F. In FIG. 6D, the side wall material 640 was dispensed such that the edges of the light polarizer 630 were still exposed. In FIG. 6E, the edges of the light polarizer 630 were covered by the side wall material 640. FIG. 6F shows the case when the side wall material 640 is partially over dispensed such that the side wall material 640 includes an overhanging portion 642 over at least a portion of the top surface of the light polarizer 630. FIG. 6G shows the embodiment of FIG. 6F, but further including a protective layer 650 formed over each of the plurality of LED packages 600. It will be understood that while element 600 is described as an LED package in FIGS. 6A-6G and the LED package includes the LED dies and the intervening layer. LED package as used in other embodiments described herein may further include the adhesive layer, the intervening layer, the side wall material, the light polarizer, the optical resin cap, and/or the protective layer.

As noted elsewhere herein, the LED displays comprising the LED packages described herein may be relatively large LED displays and/or be configured to generate 3-D images. Accordingly, some aspects are related to methods comprising generating 3-D images using an LED display comprising the LED packages described herein.

The following examples are intended to illustrate certain embodiments of the present invention, but do not exemplify the full scope of the invention.

### Example 1

The following describes exemplary embodiments of LED packages.

LED packages in line with the exemplary embodiment shown in FIG. 1 were made on an RGB 1515 5065-A2 (0.62) printed circuit board, using S-08R1SUZ/S-08HGAUD-C/S-08HBAUD-C 8 mils LED dies bonded to the printed circuit board using Au wire bond. An intervening silicone layer containing 1.5 wt % or 5 wt % diffusing powder, an adhesive layer comprising epoxy 255A/B and silicone 6140 were used. In this case, light polarizers comprising light polarizing films configured to circular polarize the light from the LEDs were used. Side wall comprising Epoxy 255ABCD (9:8:3.6:1) and 15 wt % black dye were applied and cured at 110° C. for 5 hours. Optical resin caps that were 0.22-0.29 mm thick were cured at a normal temperature and formed directly above the light polarizers.

Tables 1 and 2 show the experimental power, luminous intensity, and contrast ratios (e.g., the ratio of right-to-left circular polarized light) as a function of the amount of diffusing powder observed for four exemplary pixels (e.g., LED packages), as well as thickness of the entire pixel, constructed using the above methods.

TABLE 1
Power and brightness for four LED packages
as a function of diffusing powder.

| | | | | | Luminous | | |
|---|---|---|---|---|---|---|---|
| | Diffusing | Power | | | intensity | | |
| | powder | (mW) | | | (mcd) | | |
| Sample | (wt %) | R | G | B | R | G | B |
| 1 | 1.5 | 0.33 | 0.23 | 0.26 | 34.80 | 54.01 | 8.57 |
| 2 | 1.5 | 0.22 | 0.17 | 0.19 | 23.86 | 39.43 | 5.92 |
| 3 | 5 | 0.25 | 0.19 | 0.21 | 33.54 | 52.80 | 6.88 |
| 4 | 5 | 0.25 | 0.20 | 0.21 | 28.57 | 45.54 | 6.93 |

TABLE 2
LED contrast for four LED packages as a function of diffusing
powder, and corresponding pixel thickness for each pixel.

| | Diffusing | Contrast Ratio | | | Pixel thickness |
|---|---|---|---|---|---|
| Sample | powder (wt %) | R | G | B | (μm) |
| 1 | 1.5 | 1:39 | 1:49 | 1:27 | 1105.22 |
| 2 | 1.5 | 1:37 | 1:37 | 1:27 | 1059.65 |
| 3 | 5 | 1:39 | 1:55 | 1:30 | 1104.76 |
| 4 | 5 | 1:51 | 1:68 | 1:53 | 1249.88 |

### Example 2

The following describes the contrast ratios measured for an exemplary embodiment of an LED package.

As described elsewhere herein, the overhanging structure, when included in the LED package, is configured to reduce and/or eliminate stray light from being emitted from the edge of the light polarizer, thereby improving the contrast ratio of light emitted from the LED package. In the present example, the contrast ratio of right-to-left circular polarize light emitted from two LED packages was tested. The LED packages were constructed as outlined in Example 1. The first LED package comprised a side wall without an overhanging structure, and the second LED package comprised a side wall including an overhanging structure. Table 3 shows the contrast ratios of light emitted from the green LED for each of the first and second LED package, showing an improvement in the contrast ratio when the overhanging structure is present in the LED package due to the reduction and/or elimination of stray light (e.g., non-polarized light).

TABLE 3
Contrast ratios of light emitted from LED packages
with and without an overhanging structure.

| LED Package | Overhanging structure? | Contrast Ratio |
|---|---|---|
| First | No | 107:1 |
| Second | Yes | 189:1 |

### Example 3

This example describes contrast ratios obtained for LED displays as a function of the amount of side wall material between the LED packages.

LED displays were made as described in the context of FIGS. 6A-6F, with no side wall material, partial dispensing of the side wall material, complete dispensing of the side wall material between adjacent LED packages, and complete filling with a slight overhang. The light polarizers of the LED displays were arranged on the plurality of LED packages as shown in FIG. 5 for left and right circular light polarizers to circularly polarize the light. Contrast ratios between left and right circularly polarized light were then determined for the different LED displays. Table 4 shows the results for when no side wall material was dispensed between adjacent LED packages (FIG. 6C), a side wall material was is dispensed such that the it extends vertically only part way from the substrate to the top of the light polarizer, FIG. 6D), when the side wall material was dispensed such that it extends vertically from the substrate to the top of the light polarizer (FIG. 6E), and when the side wall material was over dispensed such that there was a partial overhanging portion over the light polarizer.

TABLE 4
Contrast ratios obtained for LED packages with varying amounts
of side wall material dispensed between adjacent LED packages.

| Amount of side wall material dispensed | Contrast ratio |
|---|---|
| None | 18:1 |
| Part way from substrate to top of light | 20:1 |
| polarizer | |
| From substrate to top of light polarizer | 191:1 |
| Over dispensed | 198:1 |

The results shown in Table 4 illustrate that having a side wall material extending from the substrate to the top of the light polarizer between adjacent LED packages of the LED displays unexpectedly improves the contrast ratio of circularly polarized light emitted from the LED display. The improved contrast ratio may be advantageous for certain displays, such as 3-D displays.

### Example 4

This Example describes an example LED display with side wall material dispensed between the LED packages of the display.

A sample LED display was fabricated as in shown in FIGS. 6A-6G (such that the side wall material is over dispensed). A control LED display was also fabricated, being substantially the same as the sample LED display but with the side wall material being underfilled as shown in FIG. 6D.

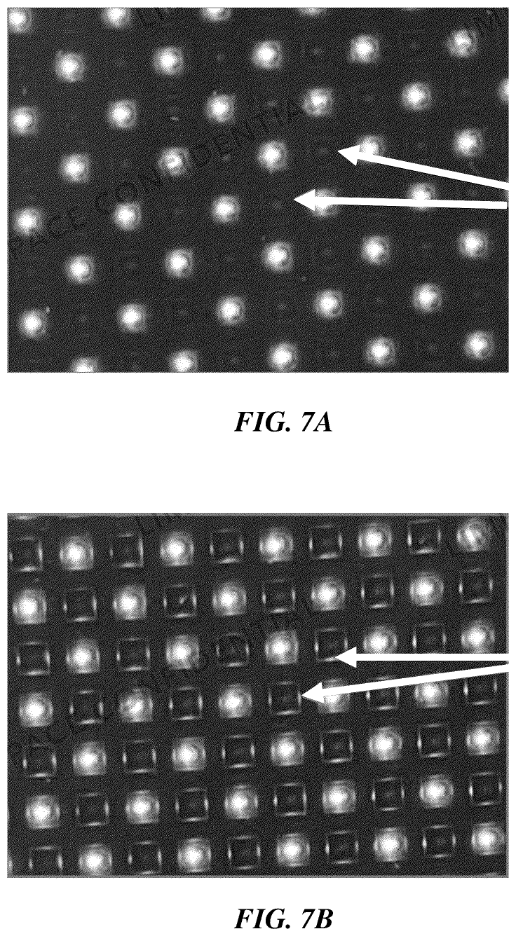

FIG. 7A shows the sample LED display and FIG. 7B shows the control LED display. The displays were imaged through a circularly polarized filter such that only every other LED package of the LED display should be seen (i.e., due to the oppositely circularly polarized light being filtered out). The image in FIG. 7A shows that the presence of the side wall material up to the top of the light polarizer leads to an LED display where every other LED package is illuminated, and accordingly the other LED packages are not seen. See arrows pointing to LED packages that do not appear to be illuminated in FIG. 7A. This indicates a high contrast ratio between the right and left circularly polarized LED packages of the LED display in FIG. 7A. In contrast, the control LED display where the side wall material is underfilled is imaged in FIG. 7B. The arrows in this image point to stray light that escapes from the LED packages without passing through the respective light polarizer and is thus observable through the circularly polarized filter (i.e., because the light is unpolarized). This results in lower contrast ratios of the control LED display in FIG. 7B where the side wall material is underfilled.

These results visualize that the side wall material between LED packages may effectively increase the contrast ratios of the LED display, which may advantageously lead to better image generation therewith.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

1. A method of manufacturing a circularly polarized LED display, comprising:
providing a plurality of LED packages, each of the plurality of the LED packages comprising:
a red LED die in electrical communication with a substrate;
a green LED die in electrical communication with the substrate;
a blue LED die in electrical communication with the substrate; and
an intervening layer formed over each of the LED dies;
forming an adhesive layer over each of the plurality of LED packages; and
placing a light polarizer over each of the plurality of LED packages, each of the light polarizers configured to polarize light emitted from the LED packages; and
dispensing a side wall material between adjacent LED packages.

2. The method of claim 1, further comprising forming an overhanging portion of a side wall over at least one of the LED packages of the plurality of the LED packages.

3. The method of claim 1, further comprising forming a protective layer over at least some of the plurality of LED packages.

4. The method of claim 1, wherein placing the light polarizer comprising using a pick and place machine.

5. The method of claim 1, further comprising pre-cutting the light polarizer.

6. The method of claim 5, wherein pre-cutting the light polarizer comprising cutting the light polarizer with a UV laser.

7. The method of claim 1, further comprising exposing the plurality of LED packages to a vacuum.

8. The method of claim 1, wherein the light polarizer is configured to circular polarize light passing therethrough.

9. The method of claim 1, further comprising curing the ide wall material.

10. The method of claim 1, further comprising emitting circularly polarized light from the plurality of LED packages of the LED display.

11. An LED display, comprising:
a plurality of LED packages, each of the plurality comprising:
a substrate;
a red LED die in electrical communication with the substrate;
a green LED die in electrical communication with the substrate;
a blue LED die in electrical communication with the substrate;
an intervening layer formed over each of the LED dies;
an adhesive layer formed over the intervening layer;
a light polarizer formed over the adhesive layer, the light polarizer configured to polarize light emitted from the LED dies; and
a side wall extending vertically from the substrate, the side wall including an upper overhanging portion that extends over a section of the light polarizer; and
a protective layer formed over the plurality of LED packages.

12. The LED display of claim 11, wherein the plurality of LED packages is configured to emit circularly polarized light.

13. The LED display of claim 12, wherein the LED packages are arranged such that every other LED package is configured to emit left circular polarized light and the remaining LED packages are configured to emit right circular polarized light.

14. The LED display of claim 11, wherein the intervening layer comprises silicone.

15. The LED display of claim 11, wherein the intervening layer is formed directly on the LED dies.

16. The LED display of claim 11, wherein the adhesive layer is formed directly on the intervening layer.

17. The LED display of claim 11, wherein the light polarizer is formed directly on the adhesive layer.

18. The LED display of claim 11, wherein the light polarizer is configured to circularly polarize light emitted from the LED dies.

19. The LED display of claim 11, wherein the light polarizer comprises a linear polarizer and a quarter wave plate.

20. The LED display of claim 11, wherein a first side of the side wall is in contact with respective sides of the intervening layer, the adhesive layer, and the light polarizer.

21. The LED display of claim 11, wherein a top surface of the protective layer is substantially flat.

22. The LED display of claim 11, wherein a top surface of the protective layer is convex.

23. The method of claim 1, wherein dispensing the side wall material between adjacent LED packages comprises dispensing the side wall material using one or more inkjets.
